(19) United States
(12) Patent Application Publication
(10) Pub. No.: US 2019/0214283 A1
(43) Pub. Date: Jul. 11, 2019

(54) PROCESS SYSTEM OF PERFORMING FABRICATION PROCESS, AND TORQUE INITIATED LIFTING TOOL INCLUDED THEREIN

(71) Applicant: Samsung Electronics Co., Ltd., Suwon-si (KR)

(72) Inventors: Matthew JESTER, Austin, TX (US); Robert BELL, Austin, TX (US); Robert STEBBINS, Round Rock, TX (US); Soren SPRISSLER, Austin, TX (US)

(21) Appl. No.: 15/867,658

(22) Filed: Jan. 10, 2018

(51) Int. Cl. H01L 21/67; B66F 11/00

(52) U.S. Cl. CPC H01L 21/67196; B66F 11/00

(57) ABSTRACT

A process system of performing a fabrication process on a wafer includes a wafer storage cassette, process chambers, a transfer chamber having a body and a lid that detachably covers the body, a frame configured to support the transfer chamber, and a lifting tool connected to the lid and extended from the lid over a portion of the frame. The body of the transfer chamber is connected to the wafer storage cassette and the plurality of process chambers so that the wafer is transferred from the wafer storage cassette through the body of the transfer chamber to one of the process chambers.

### TECHNICAL FIELD

The present inventive concept relates to a process system of performing a fabrication process and a torque initiated lifting tool included therein.

### DISCUSSION OF RELATED ART

Multi-chamber process systems are widely used in a fabrication of semiconductor devices. With multi-chamber process systems, various processes are performed in the multi-chamber process systems. Multi-chamber process systems include a transfer chamber to facilitate a distribution of a wafer among at least two or more process chambers. To conduct maintenance of the multi-chamber process systems, a lid of the transfer chamber is lifted. Such lifting may be performed by using a robotic arm including gas springs and pneumatic actuators or by using a pry bar. With the robotic arm, the multi-chamber systems are expensive and need extra maintenance for the mechanism of the robotic arm. In the case where the pry bar is used, applying leverage to the handle may cause damage the lid of the transfer chamber or a surface of the multi-chamber process systems on which the pry bar touches.

### SUMMARY

According to an exemplary embodiment of the present inventive concept, a process system of performing a fabrication process on a wafer includes a wafer storage cassette, process chambers, a transfer chamber having a body and a lid that detachably covers the body, a frame configured to support the transfer chamber, and a lifting tool connected to the lid and extended from the lid over a portion of the frame. The body of the transfer chamber is connected to the wafer storage cassette and the plurality of process chambers so that the wafer is transferred from the wafer storage cassette through the body of the transfer chamber to one of the process chambers.

According to an exemplary embodiment of the present inventive concept, a process system of performing a fabrication process on a wafer includes a chamber having a body and a lid that detachably covers the body, a frame configured to support the body of the chamber and a lifting tool connected to the lid and extended from the lid over a portion of the frame. The lifting tool includes a mounting plate connected to an upper surface of the lid, a threaded rod penetrating the mounting plate so that the threaded rod is disposed over the portion of the frame, a knob connected to an upper end of the threaded rod, and a pad connected to a lower end of the threaded rod.

According to an exemplary embodiment of the present inventive concept, a torque initiated lifting tool includes a mounting plate having holes, a threaded rod penetrating one of the holes, at least two fastener rods penetrating the other holes of the holes, a knob connected to an upper end of the threaded rod, and a pad connected to a lower end of the threaded rod. The at least two fasteners rods attach the mounting plate to a lid of a chamber in a process system of performing a fabrication process on a wafer.

### BRIEF DESCRIPTION OF DRAWINGS

These and other features of the present inventive concept will become more apparent by describing in detail exemplary embodiments thereof with reference to the accompanying drawings of which:

FIG. 1 shows a process system 100 of performing a fabrication process on a wafer according to an exemplary embodiment of the present inventive concept;

FIG. 2A shows a cross-sectional view taken along line I-I′ of FIG. 1 according to an exemplary embodiment of the present inventive concept;

FIG. 2B is an enlarged view of part LT of FIG. 1 according to an exemplary embodiment of the present inventive concept;

FIG. 3 shows a three-dimensional exploded view of a lifting tool according to an exemplary embodiment of the present inventive concept; and

FIG. 4 shows a torque that is applied through a lifting tool to a lid of a chamber according to an exemplary embodiment of the present inventive concept.

It will be appreciated that for simplicity and clarity of illustration, elements illustrated in the drawings have not necessarily been drawn to scale. For example, the dimensions of some of the elements are exaggerated relative to other elements for clarity. Further, where considered appropriate, reference numerals have been repeated among the drawings to indicate corresponding or analogous elements.

### DETAILED DESCRIPTION OF EXEMPLARY EMBODIMENTS

Exemplary embodiments of the present inventive concept will be described below in detail with reference to the accompanying drawings. However, the inventive concept may be embodied in different forms and should not be construed as limited to the embodiments set forth herein.

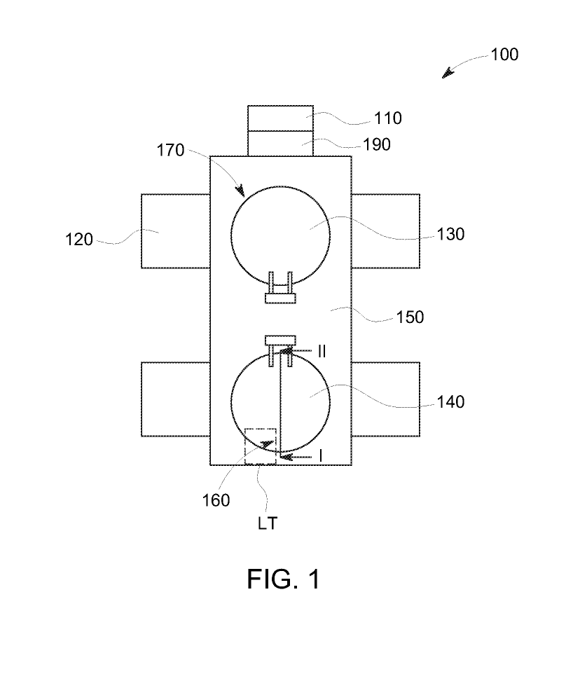

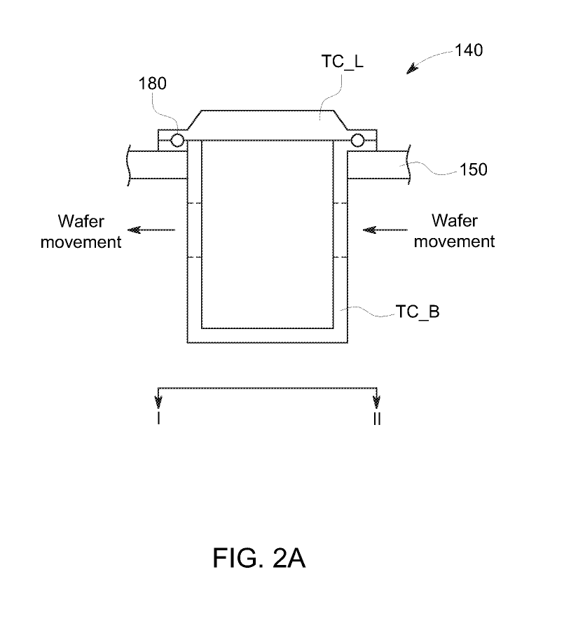

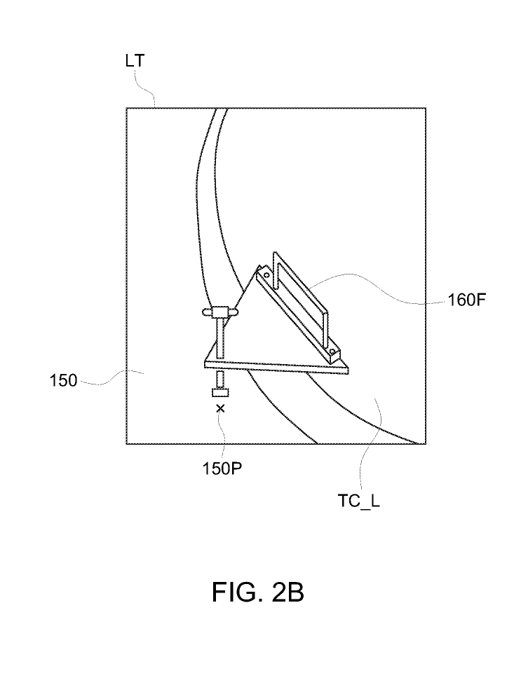

FIG. 1 shows a process system 100 of performing a fabrication process on a wafer according to an exemplary embodiment of the present inventive concept. FIG. 2A shows a cross-sectional view taken along line I-I′ of FIG. 1 according to an exemplary embodiment of the present inventive concept. FIG. 2B is an enlarged view of part LT of FIG. 1 according to an exemplary embodiment of the present inventive concept.

In FIGS. 1, 2A and 2B, the process system 100 includes a wafer storage cassette 110, a plurality of process chambers 120, a front transfer chamber 130, a rear transfer chamber 140, a frame 150, and a first lifting tool 160 and a second lifting tool 170.

The wafer storage cassette 110 may be provided in plural. For example, the process system 100 includes two wafer storage cassettes. The wafer storage cassette 110 receives a wafer to be processed in at least one of the process chambers 120 and distributes the wafer to one of the process chambers 120 through the front transfer chamber 130 or the rear transfer chamber 140 according to a process sequence. The process sequence may be controlled using a controller (not shown here).

The front transfer chamber 130 may include a robotic arm (not shown here) to transfer a wafer from the wafer storage cassette 110 to one of the process chambers 120. The robotic arm of the front transfer chamber 130 may also transfer a wafer from one of the process chambers 120 to another process chamber of the process chambers 120. The robotic arm of the front transfer chamber 130 may be controlled by the controller.

The rear transfer chamber 140 may include a robotic arm (not shown here) to transfer a wafer received from the front transfer chamber 130 to one of the process chambers 120. The robotic arm of the rear transfer chamber 140 may also transfer a wafer from one of the process chambers 120 to another one of the process chambers 120. The front transfer chamber 130 is substantially the same in structure and operation with the rear transfer chamber 140, except for their locations in the process system 100.

Each of the front transfer chamber 130 and the rear transfer chamber 140 includes a body TC_B and a lid TC_L. For the convenience of a description, the rear transfer chamber 140 will be described with reference to FIG. 2A. The body TC_B has a space to accommodate movements of robot arms (not shown here) to transfer a wafer from the front transfer chamber 130 to one of the process chambers 120 or the rear transfer chamber 140. For the front transfer chamber 130, the body TC_B has a space to accommodate movements of robot arms (not shown here) to transfer a wafer from the wafer storage cassette 110 to one of the process chambers 120. The space of the body TC_B may be in a vacuum state while the process system 100 operates. The lid TC_L covers the body TC_B to maintain the vacuum state while the process system 100 operates. An O-ring 180 is inserted between the lid TC_L and the body TC_B to seal an air leak passage therebetween when the space of the body TC_B is pumped to maintain the vacuum state.

The O-ring 180 may be a loop of elastomer with a round cross-section. The O-ring 180 is seated in a groove formed in the body TC_B and the lid TC_L and compressed while the rear transfer chamber 140 is pumped, creating a seal at the interface between the body TC_B and the lid TC_L.

To clean the interior of the body TC_B for maintenance of the process system 100, the lid TC_L is lifted and the interior of the body TC_B is exposed. The lid TC_L detachably covers the body TC_B to maintain the vacuum state while the process system 100, and is lifted for maintenance. A lifting force need to be greater than a threshold static cohesion force between the lid TC_L and the O-ring 180 or between the body TC_B and the O-ring 180. For example, the lid TC_L may be formed of a stainless steel, for example, with a diameter of 40.15 inches. In this case, the O-ring 180 may be compressed by the weight of the lid TC_L that is pulled down by a vacuum force in addition to a gravitational force. The present inventive concept is not limited thereto. For example, the diameter of the lid may be greater or smaller than 40.15 inches.

The lid TC_L has a large surface area which leads to static cohesion of the O-ring 180 with the sealing surfaces of the body TC_B and the lid TC_L. The static cohesion of the O-ring 180 may be formed on the large surface area, and thus the lid TC_L may be difficult to lift only. To lift the lid TC_L, the lifting force may be greater than the threshold static cohesion force.

The frame 150 holds the front transfer chamber 130 and the rear transfer chamber 140. In an exemplary embodiment, the process chambers 120 may be attached to the frame 150. The frame 150 may serve as a structural support of the process system 100.

Referring back to FIG. 1, the process system 100 further includes a load lock 190 disposed between the wafer storage cassette 110 and the front transfer chamber 130. With the load lock 190, the process system 100 may minimize the break of the vacuum state of the front transfer chamber 130 when transferring a wafer from the wafer storage cassette 110 to one of the process chambers 120.

The first lifting tool 160, as shown in FIG. 2B, is connected to the lid TC_L of the rear transfer chamber 140 and extended from the lid TC_L over a portion 150P of the frame 150. The process system 100 further includes a handle 160F. The handle 160F is connected to the first lifting tool 160 so that the first lifting tool 160 is interposed between the handle 160F and the frame 150. The operation of the first lifting tool 160 will be described later.

The second lifting tool 170 is connected to the lid TC_L of the front transfer chamber 130 and extended from the lid TC_L of the front transfer chamber 130 over a portion of the frame 150, like the first lifting tool 160. The first lifting tool 160 and the second lifting tool 170 may be substantially the same in structure except for their locations in the process system 100.

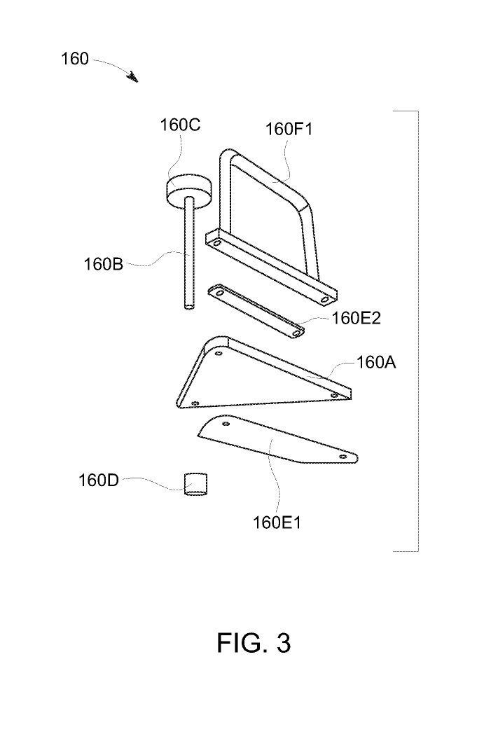

FIG. 3 shows a three-dimensional exploded view of the first lifting tool 160 according to an exemplary embodiment of the present inventive concept.

In FIG. 2, the first lifting tool 160 includes a mounting plate 160A, a threaded rod 160B, a knob 160C and a pad 160D. In an exemplary embodiment, the first lifting tool 160 may also include the handle 160F. In this case, the first lifting tool 160 includes the mounting plate 160A, the threaded rod 160B, the knob 160C, the pad 160D and the handle 160F.

The mounting plate 160A is connected to an upper surface of the lid TC_L. The mounting plate 160A is of a triangular shape. The present inventive concept is not limited thereto. For example, the mounting plate 160A may be of a rectangular shape. In this case, two threaded rods may serve to generate a torque force to lift the lid TC_L. Hereinafter, for the convenience of a description, the mounting plate 160A is assumed to be a triangular shape.

The mounting plate 160A has three vertexes near which three holes are formed. One of the three holes receives the threaded rod 160B for applying a downward force to the frame 150, and the other two holes receive two fastener rods for attaching the mounting plate 160A to the lid TC_L of the rear transfer chamber 140.

The first lifting tool 160 further includes a first Teflon layer 160E1 inserted between the mounting plate 160A and the upper surface of the lid TC_L. The first Teflon layer 160E1 may be formed of a Teflon protective material. The first Teflon layer 160E1 may serve to prevent galvanic corrosion from occurring when the mounting plate is in direct contact with the upper surface of the lid TC_L.

The first lifting tool 160 further includes a second Teflon layer 160E2 inserted between the mounting plate 160A and the handle 160F. The second Teflon layer 160E2 may be substantially the same with the first Teflon layer E1 in material.

The threaded rod 160B penetrates the mounting plate 160A so that the threaded rod 160B is disposed over the portion 150P of the frame 150. (See FIG. 2, for example).

The knob 160C is connected to an upper end of the threaded rod 160B. The pad 160D is connected to a lower end of the threaded rod 160B.

The pad 160D may be formed of a non-destructive toggle pad. The pad 160D serves as a foot to prevent excessive wear and damage to the upper surface of the frame 150. After the pad 160D lands on, or is in contact with, the portion 150P of the frame 150, turning of the knob 160C may cause the threaded rod 160B to continue to turn so that a downward force continues to be applied to the portion 150P of the frame 150.

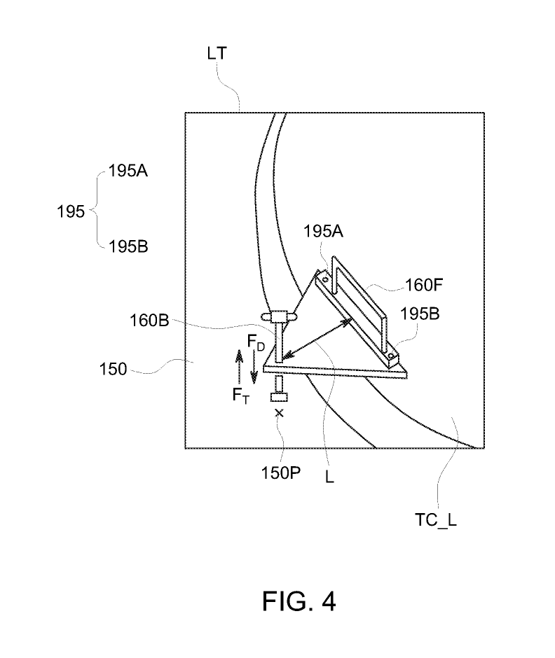

Hereinafter, the operation of the first lifting tool 160 will be described with reference to FIG. 3. FIG. 4 shows a torque F_{T} applied through the first lifting tool 160 to the lid TC_L according to an exemplary embodiment of the present inventive concept.

By rotating the knob 160C in a clockwise, for example, the threaded rod 160B moves down toward the portion 150P of the frame 150 until the pad 160D lands on the portion 150P of the frame 150. To apply a downward force F_{D} to the frame 150, the knob 160C is continuously turned so that the downward force F_{D} is applied to the portion 150P of the frame 150 and in turn generates the torque T_{f} applied upwardly to the lid TC_L as a reaction force of the downward force F_{D}. The torque F_{T} is determined as follows:

F_{T}=−F_{D}×L,

where F_{D} represents the downward force and L represents a shortest distance on the mounting plate 160A between the threaded rod 160B and a center of two holes of the mounting plate 160A. The two holes are positioned at an opposite side of the threaded rod 160B.

The first lifting tool 160 further includes a first fastener rod 195A and a second fastener rod 195B penetrating the two holes of the mounting plate 160A. The first fastener rod 195A and the second fastener rod 195B, collectively referred to as a fastener rod 195, may penetrate the two holes of the mounting plate 160A, which are disposed on the lid TC_L, and may partially penetrate into the lid TC_L so that the first lifting tool 160 is attached to the lid TC_L of the rear transfer chamber 140.

In an exemplary embodiment, the first lifting tool 160 may include the mounting plate 160A, the threaded rod 160B, the fastener rod 195, the knob 160C and a pad 160D. In an exemplary embodiment, the first lifting tool 160 may also include the handle 160F. In this case, the first lifting tool 160 includes the mounting plate 160A, the threaded rod 160B, the fastener rod 195, the knob 160C, the pad 160D and the handle 160F.

The first lifting tool 160 may be referred to as a torque initiated lifting tool. As described with reference to FIG. 3, a torque is applied to the lid TC_L through the first lifting tool 160 to overcome the static cohesion of the O-ring 180. The second lifting tool 170 operates similar to the first lifting tool 160 to lift the lid TC_L of the front transfer chamber 130, and thus the second lifting tool 170 may be also referred to as a torque initiated lifting tool.

In an exemplary embodiment, the first lifting tool 160 may be applicable to the process chambers including the process chambers 120. In this case, the first lifting tool 160 may be attached to lids of the process chambers 120, for example.

The process system 100 of FIG. 1 includes two transfer chambers, but the present inventive concept is not limited thereto. For example, the process system 100 may include one transfer chamber, or three or more transfer chambers.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

1. A process system of performing a fabrication process on a wafer, comprising:
a wafer storage cassette;
a plurality of process chambers;
a transfer chamber having a body and a lid that detachably covers the body, the body of the transfer chamber being connected to the wafer storage cassette and the plurality of process chambers so that the wafer is transferred from the wafer storage cassette through the body of the transfer chamber to one of the plurality of process chambers;
a frame configured to support the transfer chamber; and
a lifting tool connected to the lid and extended from the lid over a portion of the frame wherein the lifting tool is external to the transfer chamber.

2. The process system of claim 1, further comprising:
a handle connected to the lifting tool so that the lifting tool is interposed between the handle and the frame.

3. The process system of claim 1, further comprising:
an O-ring interposed between the lid and the body.

4. The process system of claim 1,
wherein the lifting tool includes:
a mounting plate connected to an upper surface of the lid;
a threaded rod penetrating the mounting plate so that the threaded rod is disposed over the portion of the frame;
a knob connected to an upper end of the threaded rod; and
a pad connected to a lower end of the threaded rod.

5. The process system of claim 4,
wherein the pad is a toggle pad so that after the pad is in contact with a portion of the frame, turning of the turn knob causes the threaded rod to continue to turn to exert a downward force on the portion of the frame.

6. The process system of claim 5,
wherein the downward force exerts a torque on the lid to detach the lid from the body of the transfer chamber.

7. The process system of claim 4,
wherein the mounting plate is of a triangular shape.

8. The process system of claim 7,
wherein the lifting tool further comprises two fastener rods,
wherein the mounting plate includes three holes,
wherein the threaded rod penetrates through one of the three holes that overlaps the portion of the frame, and
wherein the two fastener rods penetrate the other two holes of the three holes disposed on the lid so that the lifting tool is attached to the lid.

9. The process system of claim 4,
wherein the lifting tool further includes a Teflon layer that is interposed between the mounting plate and the upper surface of the lid.

10. A process system of performing a fabrication process on a wafer, comprising:
a chamber having a body and a lid that detachably covers the body;
a frame configured to support the body of the chamber; and
a lifting tool connected to the lid and extended from the lid over a portion of the frame,
wherein the lifting tool is external to the chamber;
wherein the lifting tool includes:
a mounting plate connected to an upper surface of the lid;
a threaded rod penetrating the mounting plate so that the threaded rod is disposed over the portion of the frame;
a knob connected to an upper end of the threaded rod; and
a pad connected to a lower end of the threaded rod.

11. The process system of claim 10,
wherein the pad is a toggle pad so that after the pad is in contact with on the portion of the frame, turning of the turn knob causes the threaded rod to continue to turn to exert a downward force on the portion of the frame.

12. The process system of claim 11,
wherein the downward force exerts a torque on the lid to detach the lid from the body of the chamber.

13. The process system of claim 10,
wherein the mounting plate is of a triangular shape.

14. A torque initiated lifting tool, comprising:
a mounting plate having a plurality of holes;
a threaded rod penetrating one of the plurality of holes;
at least two fastener rods penetrating the other holes of the plurality of holes,
wherein the at least two fasteners rods attach the mounting plate external to a lid of a chamber in a process system of performing a fabrication process on a wafer;
a knob connected to an upper end of the threaded rod; and
a pad connected to a lower end of the threaded rod.

15. The torque initiated lifting tool of claim 14,
wherein the mounting plate is of a triangular shape.

16. The torque initiated lifting tool of claim 14,
wherein the pad is a toggle pad.
